(19) United States
(12) Patent Application Publication
(10) Pub. No.: US 2025/0287812 A1
(43) Pub. Date: Sep. 11, 2025

(54) DISPLAY DEVICE

(71) Applicant: Samsung Display Co., LTD., Yongin-si (KR)

(72) Inventors: Ree Hyang KIM, Yongin-si (KR); Soo Dong KIM, Yongin-si (KR); Yun Ha RYU, Yongin-si (KR); Je Won YOO, Yongin-si (KR); Rae Young KIM, Yongin-si (KR); Jong Min OK, Yongin-si (KR); Jun Hyuk WOO, Yongin-si (KR); Seong Jin JEONG, Yongin-si (KR)

(21) Appl. No.: 18/949,862

(22) Filed: Nov. 15, 2024

(30) Foreign Application Priority Data
Mar. 8, 2024 (KR) 10-2024-0032969

(51) Int. Cl. H10K 59/80; H10K 59/122

(52) U.S. Cl. CPC H10K 59/80521; H10K 59/122; H10K 59/80516; H10K 59/80522; H10K 59/80524; H10K 59/879

(57) ABSTRACT

A display device includes: a first sub-pixel; and a second sub-pixel. Each of the first sub-pixel and the second sub-pixel includes: a first electrode; a pixel definition layer on the first electrode, and having an opening; a light emitting structure on the first electrode and the pixel definition layer; a second electrode on the light emitting structure, and having a disconnection portion; and a third electrode on the second electrode, and overlapping with the disconnection portion. A width of the disconnection portion in a first direction is 2.7% or less of a width of the opening in the first direction.

### CROSS-REFERENCE TO RELATED APPLICATION

The present application claims priority to and the benefit of Korean Patent Application No. 10-2024-0032969, filed in the Korean Intellectual Property Office on Mar. 8, 2024, the entire disclosure of which is incorporated by reference herein.

### BACKGROUND

### 1. Field

Aspects of embodiments of the present disclosure relate to a display device.

### 2. Description of the Related Art

Recently, as interest in information display is increasing, research and development on display devices are continuously being made.

### SUMMARY

Embodiments of the present disclosure may be directed to a display device having improved reliability.

However, the aspects and features of the present disclosure are not limited to those above, and the above and other aspects and features may be more clearly understood by those having ordinary skill in the art from the following description.

According to one or more embodiments of the present disclosure, a display device includes: a first sub-pixel; and a second sub-pixel. Each of the first sub-pixel and the second sub-pixel includes: a first electrode; a pixel definition layer on the first electrode, and having an opening; a light emitting structure on the first electrode and the pixel definition layer; a second electrode on the light emitting structure, and having a disconnection portion; and a third electrode on the second electrode, and overlapping with the disconnection portion. A width of the disconnection portion in a first direction is 2.7% or less of a width of the opening in the first direction.

In an embodiment, the disconnection portion may be located between the first sub-pixel and the second sub-pixel.

In an embodiment, the light emitting structure may be at least partially separated between the first sub-pixel and the second sub-pixel.

In an embodiment, the third electrode may be located within the disconnection portion.

In an embodiment, the third electrode may overlap with the opening.

In an embodiment, the third electrode may include a transparent conductive material.

In an embodiment, the third electrode may not overlap with the opening.

In an embodiment, the third electrode may include at least one of a transparent conductive material, a translucent conductive material, or an opaque conductive material.

In an embodiment, the third electrode may be located between the first sub-pixel and the second sub-pixel.

In an embodiment, a thickness of the second electrode may be 3 nm or more and 14 nm or less.

In an embodiment, a thickness of the third electrode may be 5 nm or more and 200 nm or less.

According to one or more embodiments of the present disclosure, a display device includes: a first sub-pixel; and a second sub-pixel. Each of the first sub-pixel and the second sub-pixel includes: a first electrode; a pixel definition layer on the first electrode, and having an opening; a light emitting structure on the first electrode and the pixel definition layer, and having a first disconnection portion; a second electrode on the light emitting structure, and having at least one second disconnection portion; and a third electrode on the second electrode, and overlapping with the second disconnection portion. A width of the second disconnection portion in a first direction is 2.7% or less of a width of the opening in the first direction.

In an embodiment, the second disconnection portion may overlap with the first disconnection portion.

In an embodiment, the second electrode may be located within the first disconnection portion.

In an embodiment, the third electrode may be located within the second disconnection portion.

In an embodiment, the third electrode may be located within the first disconnection portion and the second disconnection portion.

In an embodiment, the first disconnection portion and the second disconnection portion may be located between the first sub-pixel and the second sub-pixel.

In an embodiment, the third electrode may include a transparent conductive material.

In an embodiment, a thickness of the second electrode may be 3 nm or more and 14 nm or less.

In an embodiment, a thickness of the third electrode may be 5 nm or more and 200 nm or less.

According to some embodiments of the present disclosure, a light emitting structure may be at least partially separated by a separator formed in a boundary area between adjacent sub-pixels. Accordingly, a current flowing out to adjacent sub-pixels may be minimized or reduced.

According to some embodiments of the present disclosure, even if a cathode electrode is partially disconnected in the boundary area between adjacent sub-pixels, a connection electrode may be formed, and thus, the reliability of the display device may be prevented or substantially prevented from deteriorating.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a block diagram showing a display device according to an embodiment.

FIG. 2 is a block diagram showing a sub-pixel of FIG. 1 according to an embodiment.

FIG. 3 is a circuit diagram showing the sub-pixel of FIG. 2 according to an embodiment.

FIG. 4 is a plan view showing a display panel of FIG. 1 according to an embodiment.

FIG. 5 is an exploded perspective view showing a portion of the display panel of FIG. 4.

FIG. 6 is a plan view showing a pixel of FIG. 5 according to an embodiment.

FIGS. 7-12 are cross-sectional views taken along the line I-l′ of FIG. 6.

FIG. 13 is a cross-sectional view showing a light emitting structure included in any one of first to third light emitting elements of FIGS. 7 to 12 according to an embodiment.

FIG. 14 is a cross-sectional view showing a light emitting structure included in any one of the first to third light emitting elements of FIGS. 7 to 12 according to an embodiment.

FIG. 15 is a plan view showing a pixel of FIG. 5 according to an embodiment.

FIG. 16 is a plan view showing a pixel of FIG. 5 according to an embodiment.

FIG. 17 is a block diagram showing a display system according to an embodiment.

FIG. 18 is a perspective view showing an application of the display system of FIG. 17 according to an embodiment.

FIG. 19 is a drawing showing a head-mounted display device of FIG. 18 worn by a user.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense.

For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

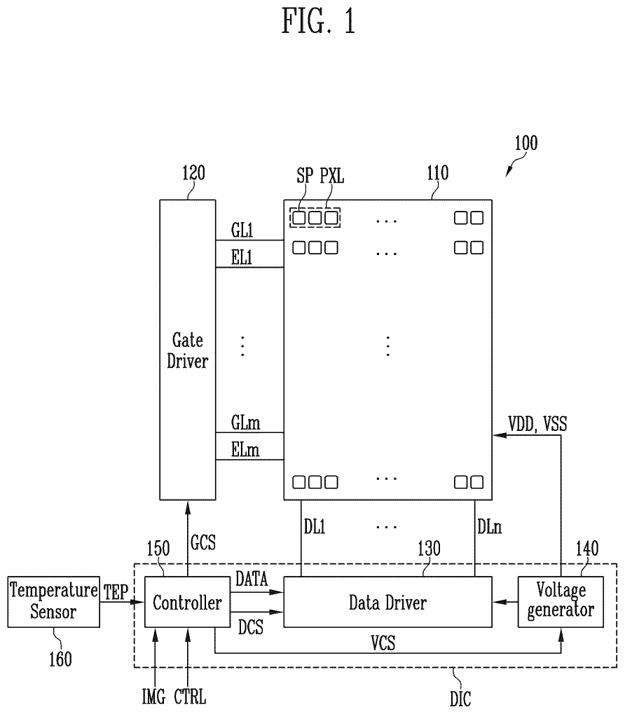

FIG. 1 is a block diagram showing a display device according to an embodiment.

Referring to FIG. 1, the display device 100 includes a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm, where m is an integer greater than 1. The sub-pixels SP may be connected to the data driver 130 through first to n-th data lines DL1 to DLn, where n is an integer greater than 1.

Each of the sub-pixels SP may include at least one light emitting element to generate light. Accordingly, each of the sub-pixels SP may generate light of a desired color (e.g., a specific or predetermined color), such as red, green, blue, cyan, magenta, yellow, or the like. Two or more sub-pixels among the sub-pixels SP may constitute one pixel PXL. For example, as shown in FIG. 1, three sub-pixels SP may constitute one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In some embodiments, the gate control signal GCS may include a start signal indicating the start of each frame, a horizontal synchronization signal for outputting gate signals in synchronization with the timing at which data signals are applied, and the like.

In some embodiments, first to m-th emission control lines EL1 to ELm connected to the sub-pixels SP in the row direction may be further provided. In this case, the gate driver 120 may include an emission control driver to control the first to m-th emission control lines EL1 to ELm, and the emission control driver may operate under control of the controller 150.

The gate driver 120 may be disposed on one side of the display panel 110. However, the present disclosure is not limited thereto. For example, the gate driver 120 may be divided into two or more physically and/or logically separated drivers, and the drivers may be disposed on one side of the display panel 110 and another side of the display panel 110 opposite to the one side. As such, the gate driver 120 may be disposed around the display panel 110 in various suitable shapes and arrangements according to various embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In some embodiments, the data control signal DCS may include a source start pulse, a source shift clock, a source output enable signal, and the like.

The data driver 130 may apply data signals having gray scale voltages corresponding to the image data DATA to the first to n-th data lines DL1 to DLn using voltages from the voltage generator 140. When a gate signal is applied to each of the first to m-th gate lines GL1 to GLm, data signals corresponding to the image data DATA may be applied to the data lines DL1 to DLn. Accordingly, the corresponding sub-pixels SP may generate light corresponding to the data signals. As such, an image may be displayed on the display panel 110.

In some embodiments, the gate driver 120 and data driver 130 may include complementary metal-oxide semiconductor (CMOS) circuit elements.

The voltage generator 140 may operate in response to a voltage control signal VCS from the controller 150. The voltage generator 140 may generate a plurality of voltages, and may provide the generated voltages to the components of the display device 100. For example, the voltage generator 140 may generate a plurality of voltages by receiving a voltage (e.g., an input voltage) input from outside the display device 100, adjusting the received voltage, and regulating the adjusted voltage.

The voltage generator 140 may generate a first power voltage VDD and a second power voltage VSS. The generated first and second power voltages VDD and VSS may be applied to the sub-pixels SP. The first power voltage VDD may have a relatively high voltage level, and the second power voltage VSS may have a lower voltage level than that of the first power voltage VDD. In other embodiments, the first power voltage VDD or the second power voltage VSS may be provided by an external device of the display device 100.

In addition, the voltage generator 140 may generate various kinds of voltages. For example, the voltage generator 140 may generate an initialization voltage applied to the sub-pixels SP. For example, during a sensing operation to sense electrical characteristics of the transistors and/or light emitting element(s) of the plurality of sub-pixels SP, a reference voltage (e.g., a predetermined reference voltage) may be applied to the first to n-th data lines DL1 to DLn, and the voltage generator 140 may generate the reference voltage.

The controller 150 may control various operations of the display device 100. The controller 150 may receive input image data IMG from the outside and a control signal CTRL for controlling the display device 100. The controller 150 may provide the gate control signal GCS, the data control signal DCS, and the voltage control signal VCS in response to the control signal CTRL.

The controller 150 may convert the input image data IMG to suit the display device 100 or the display panel 110, and output the image data DATA. In some embodiments, the controller 150 may arrange the input image data IMG to suit the sub-pixels SP in units of rows and output the image data DATA.

Two or more components from among the data driver 130, the voltage generator 140, and/or the controller 150 may be mounted together on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. In other embodiments, at least one of the data driver 130, the voltage generator 140, or the controller 150 may be provided as a separate component (e.g., as a separate IC) from the driver integrated circuit DIC.

The display device 100 may include at least one temperature sensor 160. The temperature sensor 160 may sense the temperature of surroundings thereof, and generate temperature data TEP representing the sensed temperature. In some embodiments, the temperature sensor 160 may be disposed adjacent to the display panel 110 and/or the driver integrated circuit DIC.

The controller 150 may control various operations of the display device 100 in response to temperature data TEP. In some embodiments, the controller 150 may adjust a luminance of an image output from the display panel 110 in response to temperature data TEP. For example, the controller 150 may adjust data signals and the first and second power voltages VDD and VSS by controlling the components, such as the data driver 130 and/or the voltage generator 140.

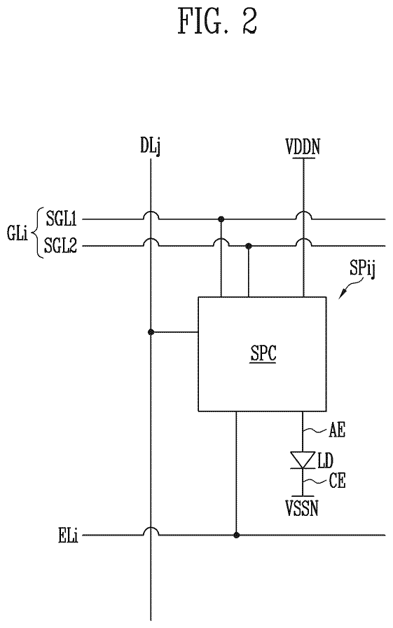

FIG. 2 is a block diagram showing a sub-pixel of FIG. 1 according to an embodiment. In FIG. 2, the sub-pixel SPij arranged in an i-th row (where i is an integer greater than or equal to 1 and less than or equal to m) and a j-th column (where j is an integer greater than or equal to 1 and less than or equal to n) from among the sub-pixels SP described above with reference to FIG. 1 may be shown as an example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be a node that transmits the first power voltage VDD described above with reference to FIG. 1, and the second power voltage node VSSN may be a node that transmits the second power voltage VSS described above with reference to FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to the i-th gate line GLi among the first to m-th gate lines GL1 to GLm described above with reference to FIG. 1, the i-th emission control line ELi among the first to m-th emission control lines EL1 to ELm, and the j-th data line DLj among the first to n-th data lines DL1 to DLn. The sub-pixel circuit SPC may control the light emitting element LD depending on signals received through these signal lines.

The sub-pixel circuit SPC may operate in response to a gate signal received through the i-th gate line GLi. The i-th gate line GLi may include one or more sub-gate lines. In some embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. In other words, when the i-th gate line GLi includes two or more sub-gate lines, the sub-pixel circuit SPC may operate in response to the gate signals received through the corresponding sub-gate lines.

The sub-pixel circuit SPC may operate in response to an emission control signal received through the i-th emission control line ELi. In some embodiments, the i-th emission control line ELi may include one or more sub emission control lines. When the i-th emission control line ELi includes two or more sub emission control lines, the sub-pixel circuit SPC may operate in response to the emission control signals received through the corresponding sub emission control lines.

The sub-pixel circuit SPC may receive a data signal through the j-th data line DLj. The sub-pixel circuit SPC may store a voltage corresponding to a data signal in response to at least one of the gate signals received through the first and second sub-gate lines SGL1 and SGL2. The sub-pixel circuit SPC may adjust the current flowing from the first power voltage node VDDN through the light emitting element LD to the second power voltage node VSSN depending on the stored voltage, in response to the light emission control signal received through the i-th light emission control line ELi. Accordingly, the light emitting element LD may generate light having a luminance corresponding to the data signal.

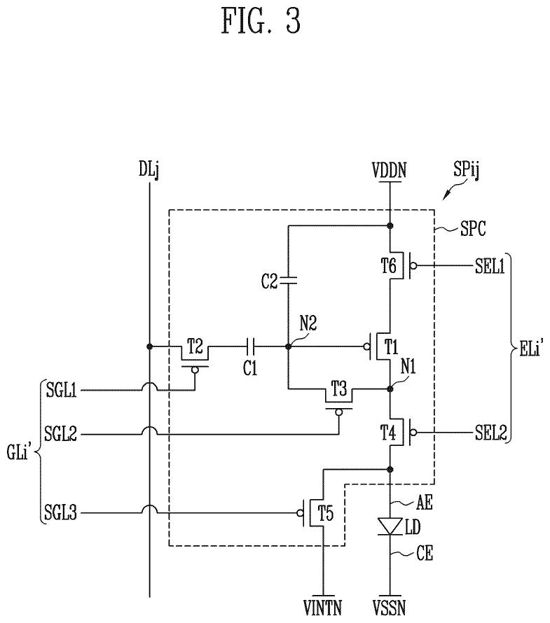

FIG. 3 is a circuit diagram showing the sub-pixel of FIG. 2 according to an embodiment.

Referring to FIG. 3, the sub-pixel SPij may include the sub-pixel circuit SPC and the light emitting element LD.

The sub-pixel circuit SPC may be connected to an i-th gate line GLi′, an i-th emission control line ELi′, and the j-th data line DLj. Compared to the i-th gate line GLi described above with reference to FIG. 2, the i-th gate line GLi′ may further include a third sub-gate line SGL3. Compared to the i-th emission control line ELi described above with reference to FIG. 2, the i-th emission control line ELi′ may include a first sub emission control line SEL1 and a second sub emission control line SEL2.

The sub-pixel circuit SPC may include first to sixth transistors T1 to T6, and first and second capacitors C1 and C2.

The first transistor T1 may be connected between the first power voltage node VDDN and a first node N1. A gate of the first transistor T1 may be connected to a second node N2, and thus, the first transistor T1 may be turned on depending on the voltage level of the second node N2. The first transistor T1 may be referred to as a driving transistor.

The second transistor T2 may be connected between the j-th data line DLj and the second node N2. A gate of the second transistor T2 may be connected to the first sub-gate line SGL1, and thus, the second transistor T2 may be turned on in response to the gate signal of the first sub-gate line SGL1. The second transistor T2 may be referred to as a switching transistor.

The third transistor T3 may be connected between the first node N1 and the second node N2. A gate of the third transistor T3 may be connected to the second sub-gate line SGL2, and thus, the third transistor T3 may be turned on in response to the gate signal of the second sub-gate line SGL2.

The fourth transistor T4 may be connected between the first node N1 and the anode electrode AE of the light emitting element LD. A gate of the fourth transistor T4 may be connected to the second sub emission control line SEL2, and thus, the fourth transistor T4 may be turned on in response to the emission control signal of the second sub emission control line SEL2.

The fifth transistor T5 may be connected between the anode electrode AE of the light emitting element LD and an initialization voltage node VINTN. The initialization voltage node VINTN may transmit an initialization voltage. In some embodiments, the initialization voltage may be provided by the voltage generator 140 described above with reference to FIG. 1. In other embodiments, the initialization voltage may be provided by an external device of the display device 100. A gate of the fifth transistor T5 may be connected to the third sub-gate line SGL3, and accordingly, the fifth transistor T5 may be turned on in response to the gate signal of the third sub-gate line SGL3.

The sixth transistor T6 may be connected between the first power voltage node VDDN and the first transistor T1. A gate of the sixth transistor T6 may be connected to the first sub emission control line SEL1, and thus, the sixth transistor T6 may be turned on in response to the emission control signal of the first sub emission control line SEL1.

The first capacitor C1 may be connected between the second transistor T2 and the second node N2. The second capacitor C2 may be connected between the first power voltage node VDDN and the second node N2.

As described above, the sub-pixel circuit SPC may include the first to sixth transistors T1 to T6, and the first and second capacitors C1 and C2. However, the present disclosure is not limited thereto. The sub-pixel circuit SPC may be implemented as any one of various suitable kinds of circuits including a plurality of transistors and one or more capacitors. For example, the sub-pixel circuit SPC may include two transistors and one capacitor. According to some embodiments, the number of sub-gate lines included in the i-th gate line GLi′ and the number of sub-emission control lines included in the i-th emission control line ELi′ may also be variously modified as needed or desired.

The first to sixth transistors T1 to T6 may be P-type transistors. Each of the first to sixth transistors T1 to T6 may be a metal oxide silicon field effect transistor (MOSFET). However, the present disclosure is not limited thereto. For example, at least one of the first to sixth transistors T1 to T6 may be an N-type transistor.

In some embodiments, the first to sixth transistors T1 to T6 may include an amorphous silicon semiconductor, a monocrystalline silicon semiconductor, a polycrystalline silicon semiconductor, an oxide semiconductor, or the like.

The light emitting element LD may include the anode electrode AE, the cathode electrode CE, and an emission layer. The emission layer may be disposed between the anode electrode AE and the cathode electrode CE. After the data signal transmitted through the j-th data line DLj is reflected in the voltage of the second node N2, the fourth and sixth transistors T4 and T6 may be turned on when the emission control signals of the first and second sub emission control lines SEL1 and SEL2 are enabled at a low level. The first transistor T1 may be turned on depending on the voltage of the second node N2, and thus, a current may flow from the first power voltage node VDDN to the second power voltage node VSSN. The light emitting element LD may emit light depending on the amount of the current flowing.

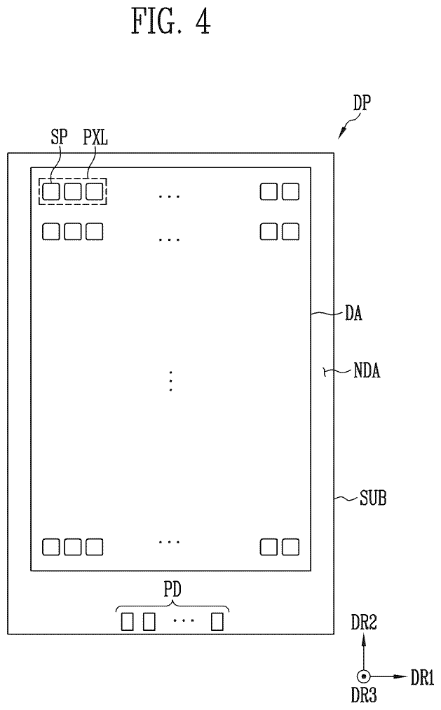

FIG. 4 is a plan view showing the display panel of FIG. 1 according to an embodiment.

Referring to FIG. 4, the display panel DP may be an embodiment of the display panel 110 described above with reference to FIG. 1, and may include a display area DA and a non-display area NDA. The display panel DP displays an image through the display area DA. The non-display area NDA may be disposed around the display area DA. For example, the non-display area NDA may surround (e.g., around a periphery of) the display area DA.

The display panel DP may include a substrate SUB, sub-pixels SP, and pads PD.

When the display panel DP is used as a display screen of a head mounted display (HMD), a virtual reality (VR) device, a mixed reality (MR) device, an augmented reality (AR) device, or the like, the display panel DP may be disposed to be very close to the user's eyes. In this case, the sub-pixels SP having a relatively high integration may be desired. To increase the integration of the sub-pixels SP, the substrate SUB may be provided as a silicon substrate. The sub-pixels SP and/or the display panel DP may be formed on the substrate SUB, which is a silicon substrate. The display device 100 (e.g., see FIG. 1) including the display panel DP formed on the substrate SUB, which is a silicon substrate, may be referred to as an OLED on silicon (OLEDoS) display device.

The sub-pixels SP may be disposed in the display area DA on the substrate SUB. The sub-pixels SP may be arranged in a matrix form along the first direction DR1 and the second direction DR2 that crosses or intersects the first direction DR1. However, the present disclosure is not limited thereto. For example, the sub-pixels SP may be arranged in a zigzag shape along the first direction DR1 and the second direction DR2. For example, the sub-pixels SP may be disposed in an RGBG or diamond-shaped arrangement (e.g. a PENTILE® shape, PENTILE® being a duly registered trademark of Samsung Display Co., Ltd.). The first direction DR1 may be a row direction, and the second direction DR2 may be a column direction.

Two or more sub-pixels among the plurality of sub-pixels SP may constitute one pixel PXL.

Components for controlling the sub-pixels SP may be disposed in the non-display area NDA on the substrate SUB. For example, the lines connected to the sub-pixels SP, such as the first to m-th gate lines GL1 to GLm and the first to n-th data lines DL1 to DLn described above with reference to FIG. 1, may be disposed on the non-display area NDA.

At least one of the gate driver 120, the data driver 130, the voltage generator 140, the controller 150, and/or the temperature sensor 160 described above with reference to FIG. 1 may be integrated in the non-display area NDA of the display panel DP. In some embodiments, the gate driver 120 may be mounted on the display panel DP, and disposed in the non-display area NDA. In other embodiments, the gate driver 120 may be implemented as an integrated circuit separate from the display panel DP. In some embodiments, the temperature sensor 160 may be disposed in the non-display area NDA to detect the temperature of the display panel DP.

Pads PD may be disposed in the non-display area NDA on the substrate SUB. The pads PD may be electrically connected to the sub-pixels SP through the lines. For example, the pads PD may be connected to the sub-pixels SP through the first to n-th data lines DL1 to DLn.

The pads PD may interface the display panel DP to other components of the display device 100 (e.g., see FIG. 1). In some embodiments, voltages and signals used for the operations of the components included in the display panel DP may be provided from the driver integrated circuit DIC through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In some embodiments, the circuit board may be electrically connected to the pads PD using a conductive adhesive member, such as an anisotropic conductive film. The circuit board may be a flexible circuit board (FPCB) or a flexible film made of a flexible material. The driver integrated circuit DIC may be mounted on the circuit board, and electrically connected to the pads PD.

In some embodiments, the display area DA may have various suitable shapes. The display area DA may have a closed loop shape including straight and/or curved sides. For example, the display area DA may have various suitable shapes, such as a polygon, a circle, a semicircle, or an ellipse.

In some embodiments, the display panel DP may have a flat or substantially flat display surface. In other embodiments, the display panel DP may have a display surface that is at least partially rounded or curved. In some embodiments, the display panel DP may be bendable, foldable, or rollable. In such cases, the display panel DP and/or the substrate SUB may include various suitable materials having flexible properties.

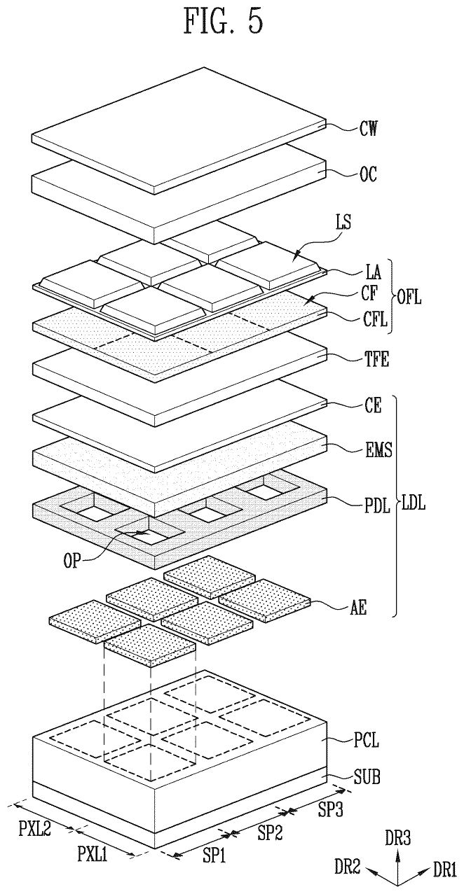

FIG. 5 is an exploded perspective view showing a portion of the display panel of FIG. 4.

In FIG. 5, for convenience of illustration, portions of the display panel DP corresponding to two pixels PXL1 and PXL2 among the pixels PXL described above with reference to FIG. 4 may be schematically shown. Portions of the display panel DP corresponding to the other remaining pixels PXL may have the same or substantially the same configuration as those of the two pixels PXL1 and PXL2.

Referring to FIGS. 4 and 5, each of the first and second pixels PXL1 and PXL2 may include first to third sub-pixels SP1, SP2, and SP3. However, the present disclosure is not limited thereto. For example, each of the first and second pixels PXL1 and PXL2 may include four sub-pixels or two sub-pixels.

In FIG. 5, the first to third sub-pixels SP1, SP2, and SP3 may be illustrated as having quadrangle shapes having the same sizes as each other when viewed from the third direction DR3 (e.g., in a plan view) crossing the first and second directions DR1 and DR2. However, the present disclosure is not limited thereto. The first to third sub-pixels SP1, SP2, and SP3 may be variously modified as needed or desired to have various suitable shapes.

The display panel DP may include a substrate SUB, a pixel circuit layer PCL, a light emitting element layer LDL, an encapsulation layer TFE, an optical functional layer OFL, an overcoat layer OC, and a cover window CW.

In some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In other embodiments, the substrate SUB may include a glass substrate. In other embodiments, the substrate SUB may include a polyimide (PI) substrate.

The pixel circuit layer PCL may be disposed on the substrate SUB. The substrate SUB and/or the pixel circuit layer PCL may include insulating layers, and conductive patterns disposed between the insulating layers. The conductive patterns of the pixel circuit layer PCL may function as at least a portion of the circuit elements, the lines, or the like. The conductive patterns may include copper, but the present disclosure is not limited thereto.

The circuit elements may include a sub-pixel circuit SPC (e.g., see FIG. 2) for each of the first to third sub-pixels SP1, SP2, and SP3. The sub-pixel circuit (SPC) may include transistors and one or more capacitors. Each transistor may include a semiconductor portion including a source region, a drain region, and a channel region, and a gate electrode overlapping with the semiconductor portion. In some embodiments, when the substrate SUB may be provided as a silicon substrate, the semiconductor portion may be included in the substrate SUB, and the gate electrode may be included in the pixel circuit layer PCL as a conductive pattern of the pixel circuit layer PCL. In some embodiments, when the substrate SUB is provided as a glass substrate or a PI substrate, the semiconductor portion and the gate electrode may be included in the pixel circuit layer PCL. Each capacitor may include electrodes that are spaced apart from each other. For example, each capacitor may include the electrodes that are spaced apart from each other on a plane (e.g., in a plan view) defined by the first and second directions DR1 and DR2. For example, each capacitor may include the electrodes that are spaced apart from each other in the third direction DR3 with an insulating layer interposed therebetween.

The lines of the pixel circuit layer PCL may include the signal lines connected to each of the first to third sub-pixels SP1, SP2, and SP3, for example, such as the gate line, the emission control line, the data line, and the like. The lines may further include a line connected to the first power voltage node VDDN described above with reference to FIG. 2. The lines may further include a line connected to the second power voltage node VSSN described above with reference to FIG. 2.

The light emitting element layer LDL may include the anode electrodes AE (e.g., a first electrode), a pixel definition layer PDL, a light emitting structure EMS, and the cathode electrode CE (e.g., a second electrode).

The anode electrodes AE may be disposed on the pixel circuit layer PCL. The anode electrodes AE may contact the circuit elements of the pixel circuit layer PCL. The anode electrodes AE may include an opaque conductive material capable of reflecting light, but the present disclosure is not limited thereto.

The pixel definition layer PDL may be disposed on the anode electrodes AE. The pixel definition layer PDL may include openings OP exposing a portion of each of the anode electrodes AE. The openings OP of the pixel defining layer PDL may be understood as emission areas corresponding to the first to third sub-pixels SP1 to SP3, respectively.

In some embodiments, the pixel definition layer PDL may include an inorganic material. For example, the pixel definition layer PDL may include a plurality of stacked inorganic layers. In this case, the pixel definition layer PDL may include silicon oxide (SiOx) and silicon nitride (SiNx). In other embodiments, the pixel definition layer PDL may include an organic material. However, the material of the pixel definition layer PDL is not limited thereto.

The light emitting structure EMS may be disposed on the anode electrodes AE exposed by the openings OP of the pixel definition layer PDL. The light emitting structure EMS may include an emission layer to generate light, an electron transport layer to transport electrons, and a hole transport layer to transport holes.

In some embodiments, the light emitting structure EMS may fill the opening OP of the pixel definition layer PDL, and may be entirely disposed on the pixel definition layer PDL. In other words, the light emitting structure EMS may extend over the first to third sub-pixels SP1 to SP3. In this case, at least some of the layers in the light emitting structure EMS may be broken or bent at boundaries between the first to third sub-pixels SP1 to SP3. However, the present disclosure is not limited thereto. For example, portions of the light emitting structure EMS corresponding to the first to third sub-pixels SP1 to SP3 may be spaced apart (e.g., separated) from each other, and each of them may be disposed within a corresponding opening OP of the pixel defining layer PDL.

The cathode electrode CE may be disposed on the light emitting structure EMS. The cathode electrode CE may extend over the first to third sub-pixels SP1 to SP3. In other words, the cathode electrode CE may serve as a common electrode for the first to third sub-pixels SP1 to SP3.

The cathode electrode CE may be a thin metal layer having a thickness sufficient to transmit light emitted from the light emitting structure EMS. The cathode electrode CE may be formed of a metal material or a transparent conductive material to have a relatively thin thickness. In some embodiments, the cathode electrode CE may include at least one of various suitable transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), and/or a suitable mixture thereof. However, the material of the cathode electrode CE is not limited thereto.

Any one of the anode electrodes AE, a portion of the light emitting structure EMS overlapping therewith, and a portion of the cathode electrode CE overlapping therewith may be understood as constituting one light emitting element LD (e.g., see FIG. 2). In other words, each of the light emitting elements LD of the first to third sub-pixels SP1 to SP3 may include one anode electrode, a portion of the light emitting structure EMS overlapping with the anode electrode, and a portion of the cathode electrode CE overlapping with the anode electrode. In each of the first to third sub-pixels SP1 to SP3, holes injected from the anode electrode AE and electrons injected from the cathode electrode CE may be transported into the emission layer of the light emitting structure EMS to generate excitons, and when the excitons transition from an excited state to a ground state, light may be generated. The luminance of light may be determined depending on the amount of current flowing through the emission layer. Depending on the configuration of the emission layer, the wavelength range of the generated light may be determined.

The encapsulation layer TFE may be disposed on the cathode electrode CE. The encapsulation layer TFE may cover the light emitting element layer LDL and/or the pixel circuit layer PCL. The encapsulation layer TFE may prevent or substantially prevent oxygen and/or moisture from penetrating into the light emitting element layer LDL. In some embodiments, the encapsulation layer TFE may include a structure in which one or more inorganic layers and one or more organic layers are alternately stacked on one another. For example, the inorganic layer may include silicon nitride, silicon oxide, or silicon oxynitride (SiOxNy). For example, the organic layer may include one or more organic insulating materials, such as acrylic resin, epoxy resin, phenol resin, polyamide resin, polyimide resin, unsaturated polyester resin, poly phenylene ether resin, polyphenylene sulfide resin, or benzocyclobutene (BCB). However, the materials of the organic and inorganic layers of the encapsulation layer TFE are not limited thereto.

To improve the encapsulation efficiency of the encapsulation layer TFE, the encapsulation layer TFE may further include a thin layer including or containing aluminum oxide (AlOx). The thin layer containing aluminum oxide may be disposed on the upper surface of the encapsulation layer TFE facing the optical functional layer OFL and/or on the lower surface of the encapsulating layer TFE facing the light emitting element layer LDL.

The thin layer containing aluminum oxide may be formed through an atomic layer deposition (ALD) method. However, the present disclosure is not limited thereto. The encapsulation layer TFE may further include a thin layer formed of at least one of various suitable materials suitable for improving the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may filter light emitted from the light emitting structure EMS, and selectively output light in a wavelength range or color corresponding to each sub-pixel. The color filter layer CFL may include color filters CF corresponding to the first to third sub-pixels SP1 to SP3, and each of the color filters CF may pass light of a desired wavelength range corresponding to that of the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. Depending on the light emitted from the light emitting structure EMS of each sub-pixel, at least some of the color filters CF may be omitted.

The lens array LA may be disposed on the color filter layer CFL. The lens array LA may include lenses LS corresponding to the first to third sub-pixels SP1 to SP3, respectively. Each of the lenses LS may improve light output efficiency by outputting the light emitted from the light emitting structure EMS through an intended path. The lens array LA may have a relatively high refractive index. For example, the lens array LA may have a higher refractive index than that of the overcoat layer OC. In some embodiments, the lenses LS may include an organic material. In some embodiments, the lenses LS may include an acrylic material. However, the material of the lenses LS is not limited thereto.

In some embodiments, compared to the opening OP of the pixel defining layer PDL, at least a portion of the color filters CF of the color filter layer CFL and at least a portion of the lenses LS of the lens array LA may be shifted in a direction parallel to or substantially parallel to the plane defined by the first and second directions DR1 and DR2. In more detail, in the central area of the display area DA, the center of the color filter CF and the center of the lens LS may be aligned with or overlap with the center of the corresponding opening OP of the pixel defining layer PDL when viewed in the third direction DR3 (e.g., in a plan view). For example, in the central area of the display area DA, the opening OP of the pixel defining layer PDL may completely overlap with the corresponding color filter CF of the color filter layer CFL and the corresponding lens LS of the lens array LA. In the area adjacent to the non-display area NDA of the display area DA, the center of the color filter CF and the center of the lens LS may be shifted in the plane direction from the center of the corresponding opening OP of the pixel defining layer PDL when viewed in the third direction DR3 (e.g., in a plan view). For example, in the area adjacent to the non-display area NDA of the display area DA, the opening OP of the pixel defining layer PDL may partially overlap with the corresponding color filter CF of the color filter layer CFL and the corresponding lens LS of the lens array LA. Accordingly, at the central area of the display area DA, light emitted from the light emitting structure EMS may be efficiently output in the normal direction of the display surface. At the outer area of the display area DA, light emitted from the light emitting structure EMS may be efficiently output in a direction inclined by an angle (e.g., a predetermined angle) with respect to the normal direction of the display surface.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various suitable materials suitable for protecting the lower layers thereof from foreign substances, such as dust, moisture, and the like. For example, the overcoat layer OC may include at least one of an inorganic insulating layer and/or an organic insulating layer. For example, the overcoat layer OC may include an epoxy, but the present disclosure is not limited thereto. The overcoat layer OC may have a lower refractive index than that of the lens array LA.

The cover window CW may be disposed on the overcoat layer OC. The cover window CW may protect the lower layers thereof. The cover window CW may have a higher refractive index than that of the overcoat layer OC. The cover window CW may include glass, but the present disclosure is not limited thereto. For example, the cover window CW may be an encapsulation glass configured to protect the components disposed thereunder. In other embodiments, the cover window CW may be omitted as needed or desired.

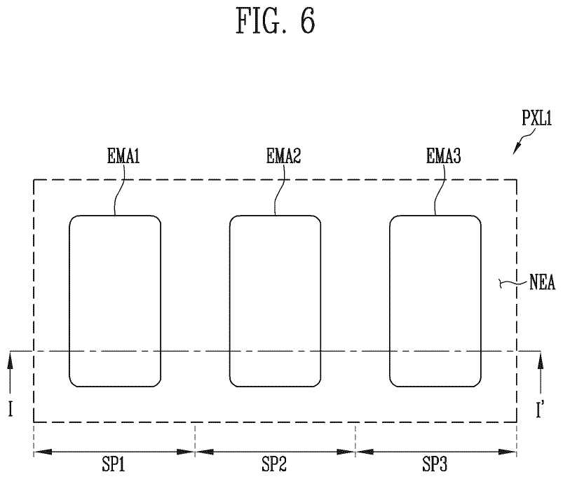

FIG. 6 is a plan view showing a pixel of FIG. 5 according to an embodiment.

In FIG. 6, the first pixel PXL1 among the first and second pixels PXL1 and PXL2 described above with reference to FIG. 5 may be schematically shown for convenience of illustration. The remaining pixels PXL may have the same or substantially the same configuration as that of the first pixel PXL1.

Referring to FIGS. 5 and 6, the first pixel PXL1 may include first to third sub-pixels SP1 to SP3 arranged along the first direction DR1.

The first sub-pixel SP1 may include a first emission area EMA1, and a non-emission area NEA around (e.g., surrounding around a periphery of) the first emission area EMA1. The second sub-pixel SP2 may include a second emission area EMA2, and a non-emission area NEA around (e.g., surrounding around a periphery of) the second emission area EMA2. The third sub-pixel SP3 may include a third emission area EMA3, and a non-emission area NEA around (e.g., surrounding around a periphery of) the third emission area EMA3.

The first emission area EMA1 may be an area where light is emitted from a portion of the light emitting structure EMS (e.g., see FIG. 5) corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel SP3. As described above with reference to FIG. 5, each emission area may be understood as a corresponding opening OP of the pixel defining layer PDL for each of the first to third sub-pixels SP1 to SP3.

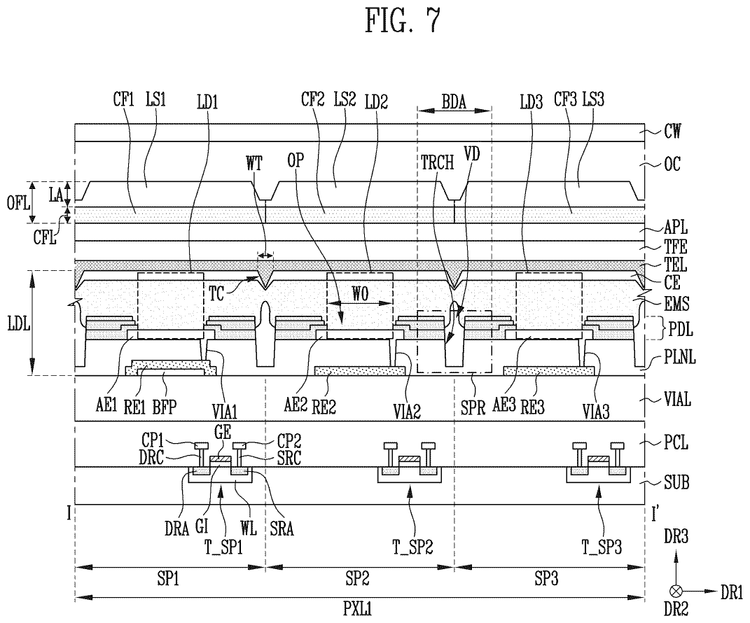

FIGS. 7 through 12 are cross-sectional views taken along the line I-I′ of FIG. 6.

Referring to FIG. 7, a substrate SUB may be provided, and a pixel circuit layer PCL may be disposed on the substrate SUB.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements for each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (e.g., see FIG. 2) of the first sub-pixel SP1. The transistor T_SP2 of the second sub-pixel SP2 may be one of the transistors included in the sub-pixel circuit SPC of the second sub-pixel SP2. The transistor T_SP3 of the third sub-pixel SP3 may be one of the transistors included in the sub-pixel circuit SPC of the third sub-pixel SP3. In FIG. 7, for convenience of illustration, one of the transistors for each of the sub-pixels is shown, and the remaining circuit elements are not shown.

The transistor T_SP1 of the first sub-pixel SP1 may include a source region SRA, a drain region DRA, and a gate electrode GE.

The source area SRA and drain area DRA may be disposed in the substrate SUB. A well WL formed through an ion implantation process may be disposed in the substrate SUB, and the source region SRA and the drain region DRA may be disposed to be spaced apart from each other in the well WL. The area between the source region SRA and the drain region DRA in the well WL may be defined as a channel region.

The gate electrode GE may overlap with the channel region between the source region SRA and the drain region DRA, and may be disposed at (e.g., in or on) the pixel circuit layer PCL. The gate electrode GE may be spaced apart from the well WL or the channel region by an insulating material, such as the gate insulating layer GI. The gate electrode GE may include a conductive material.

A plurality of layers included in the pixel circuit layer PCL may include insulating layers, and conductive patterns disposed between the insulating layers. The conductive patterns may include first and second conductive patterns CP1 and CP2. The first conductive pattern CP1 may be electrically connected to the drain region DRA through a drain connection portion DRC that penetrates one or more of the insulating layers. The second conductive pattern CP2 may be electrically connected to the source region SRA through the source connection portion SRC that penetrates one or more of the insulating layers.

As the gate electrode GE and the first and second conductive patterns CP1 and CP2 are connected to other circuit elements and/or lines, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured in the same or substantially the same manner as that of the transistor T_SP1 of the first sub-pixel SP1.

As such, the substrate SUB and the pixel circuit layer PCL may include the circuit elements of each of the first to third sub-pixels SP1 to SP3.

The via layer VIAL may be disposed on the pixel circuit layer PCL. The via layer VIAL may cover the pixel circuit layer PCL, and may have an overall flat or substantially flat surface. The via layer VIAL may planarize or substantially planarize steps on the pixel circuit layer PCL. The via layer VIAL may include at least one of silicon oxide (SiOx), silicon nitride (SiNx), or silicon carbon nitride (SiCN), but the present disclosure is not limited thereto.

The light emitting element layer LDL may be disposed on the via layer VIAL. The light emitting element layer LDL may include first to third reflective electrodes RE1 to RE3, a planarization layer PLNL, first to third anode electrodes AE1 to AE3, a pixel defining layer PDL, a light emitting structure EMS, and a cathode electrode CE.

On the via layer VIAL, the first to third reflective electrodes RE1 to RE3 may be disposed in the first to third sub-pixels SP1 to SP3, respectively. Each of the first to third reflective electrodes RE1 to RE3 may contact a corresponding circuit element disposed at (e.g., in or on) the pixel circuit layer PCL through a via penetrating the via layer VIAL.

The first to third reflective electrodes RE1 to RE3 may function as full mirrors that reflect light emitted from the light emitting structure EMS toward the display surface (e.g., toward the cover window CW). The first to third reflective electrodes RE1 to RE3 may include one or more metal materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or a suitable alloy of two or more materials selected therefrom, but the present disclosure is not limited thereto.

In some embodiments, the contact electrode may be disposed under each of the first to third reflective electrodes RE1 to RE3. The contact electrode may improve the electrical connection characteristics between the corresponding reflective electrode and the circuit elements of the pixel circuit layer PCL. The contact electrode may have a multilayered structure. The multilayered structure may include titanium (Ti), titanium nitride (TiN), tantalum nitride (TaN), and/or the like, but the present disclosure is not limited thereto. In some embodiments, the corresponding reflective electrode may be disposed between multilayers of the contact electrodes.

A buffer pattern BFP may be disposed under at least one of the first to third reflective electrodes RE1 to RE3. The buffer pattern BFP may include an inorganic material, such as silicon carbon nitride, but the present disclosure is not limited thereto. By disposing the buffer pattern BFP, the height of the corresponding reflective electrode in the third direction DR3 may be adjusted. For example, the buffer pattern BFP may be disposed between the first reflective electrode RE1 and the via layer VIAL to adjust the height of the first reflective electrode RE1.

The first to third reflective electrodes RE1 to RE3 may function as full mirrors, and the cathode electrode CE may function as a half mirror. Light emitted from the emission layer of the light emitting structure EMS may be amplified, at least in part, by reciprocating between the corresponding reflective electrode and the cathode electrode CE, and the amplified light may be output through the cathode electrode CE.

As such, a distance between each reflective electrode and the cathode electrode CE may be understood as a resonance distance for the light emitted from the emission layer of the corresponding light emitting structure EMS.

The first sub-pixel SP1 may have a shorter resonance distance than those of the other sub-pixels due to the buffer pattern BFP. The resonance distance adjusted in this way may allow light in a desired or specific wavelength range (e.g., a red color) to be effectively and efficiently amplified. Accordingly, the first sub-pixel SP1 may effectively and efficiently output light in the corresponding wavelength range.

In FIG. 7, the buffer pattern BFP is shown as being provided to the first sub-pixel SP1 and not to the second and third sub-pixels SP2 and SP3, but the present disclosure is not limited thereto. The buffer pattern BFP may also be provided to at least one of the second or third sub-pixels SP2 or SP3 to adjust the resonance distance of at least one of the second or third sub-pixels SP2 or SP3. For example, the first to third sub-pixels SP1 to SP3 may correspond to red, green, and blue, respectively. In this case, a distance between the first reflective electrode RE1 and the cathode electrode CE may be shorter than a distance between the second reflective electrode RE2 and the cathode electrode CE, and a distance between the second reflective electrode RE2 and the cathode electrode CE may be shorter than a distance between the third reflective electrode RE3 and the cathode electrode CE.

To planarize or substantially planarize the steps between the first to third reflective electrodes RE1 to RE3, the planarization layer PLNL may be disposed on the via layer VIAL and the first to third reflective electrodes RE1 to RE3. The planarization layer PLNL may generally cover the first to third reflective electrodes RE1 to RE3 and the via layer VIAL, and may have a flat or substantially flat surface. In some embodiments, the planarization layer PLNL may be omitted as needed or desired.

The anode electrodes AE1, AE2, and AE3 (e.g., first electrode) may be disposed on the planarization layer PLNL. The first to third anode electrodes AE1 to AE3 may overlap with the first to third reflective electrodes RE1 to RE3, respectively. The first to third anode electrodes AE1 to AE3 may have shapes similar to those of the first to third emission areas EMA1 to EMA3 described above with reference to FIG. 6 when viewed in the third direction DR3 (e.g., in a plan view). The first to third anode electrodes AE1 to AE3 may be connected to the first to third reflective electrodes RE1 to RE3, respectively. The first anode electrode AE1 may be connected to the first reflective electrode RE1 through the first via VIA1 penetrating the planarization layer PLNL. The second anode electrode AE2 may be connected to the second reflective electrode RE2 through the second via VIA2 penetrating the planarization layer PLNL. The third anode electrode AE3 may be connected to the third reflective electrode RE3 through the third via VIA3 penetrating the planarization layer PLNL.

In some embodiments, the first to third anode electrodes AE1 to AE3 may include at least one of various suitable transparent conductive materials, such as indium tin oxide (ITO), indium zinc oxide (IZO), zinc oxide (ZnOx), indium gallium zinc oxide (IGZO), and/or indium tin zinc oxide (ITZO). However, the materials of the first to third anode electrodes AE1 to AE3 are not limited thereto. For example, the first to third anode electrodes AE1 to AE3 may include titanium nitride.

In some embodiments, insulating layers may be further provided to adjust the height of one or more of the first to third anode electrodes AE1 to AE3. The insulating layers may be disposed between one or more of the first to third anode electrodes AE1 to AE3 and the corresponding reflective electrodes thereof. In this case, the planarization layer PLNL and/or the buffer pattern BFP may be omitted. For example, the first to third sub-pixels SP1 to SP3 may correspond to red, green, and blue, respectively. In this case, a distance between the first anode electrode AE1 and the cathode electrode CE may be shorter than a distance between the second anode electrode AE2 and the cathode electrode CE, and a distance between the second anode electrode AE2 and the cathode electrode CE may be shorter than a distance between the third anode electrode AE3 and the cathode electrode CE. The pixel defining layer PDL may be disposed on portions of the first to third anode electrodes AE1 to AE3 and the planarization layer PLNL. The pixel defining layer PDL may include openings OP exposing a portion of each of the first to third anode electrodes AE1 to AE3, respectively. Each of the openings OP of the pixel defining layer PDL may define the emission area of a corresponding one of the first to third sub-pixels SP1 to SP3. As such, the pixel defining layer PDL may be disposed in the non-emission area NEA described above with reference to FIG. 6, and may define the first to third emission areas EMA1 to EMA3 described above with reference to FIG. 6.

In some embodiments, the pixel definition layer PDL may include a plurality of inorganic insulating layers. Each of the plurality of inorganic insulating layers may include at least one of silicon oxide (SiOx) or silicon nitride (SiNx). For example, the pixel defining layer PDL may include first to third inorganic insulating layers that are sequentially stacked. The first to third inorganic insulating layers may include silicon nitride, silicon oxide, and silicon nitride, respectively. However, the present disclosure is not limited thereto. The first to third inorganic insulating layers may have a step-shaped cross section in an area adjacent to the opening OP.

A separator SPR may be provided at a boundary area BDA between neighboring sub-pixels. In other words, the separator SPR may be provided at each of the boundary areas between the sub-pixels SP in FIG. 4.

The separator SPR may cause a discontinuity to be formed within the light emitting structure EMS at the boundary area BDA. For example, the light emitting structure EMS may be broken or bent at the boundary area BDA due to the separator SPR.

The separator SPR may be provided at (e.g., in or on) the pixel definition layer PDL. The pixel definition layer PDL may include one or more trenches TRCH as the separator SPR at the boundary area BDA. In some embodiments, as shown in FIG. 7, the trench TRCH may penetrate the pixel definition layer PDL, and may further partially penetrate the planarization layer PLNL. In other embodiments, the trench TRCH may penetrate the pixel definition layer PDL and the planarization layer PLNL, and may further partially penetrate the via layer VIAL. In other embodiments, the trench TRCH may at least partially penetrate the planarization layer PLNL and/or the via layer VIAL, and a portion of the pixel definition layer PDL may be disposed within the trench TRCH.

In FIG. 7, one trench TRCH is illustrated as being provided at the boundary area BDA, but the present disclosure is not limited thereto. For example, the pixel definition layer PDL may include two or more trenches at the boundary area BDA.

Due to the trench TRCH, discontinuous portions, such as voids VD, may be formed in the light emitting structure EMS at the boundary area BDA. Some of the plurality of layers that are stacked in the light emitting structure EMS may be cut off or bent due to voids VD. For example, at least one charge generation layer included in the light emitting structure EMS may be cut off due to the voids VD. As such, the light emitting structure EMS included in the first to third sub-pixels SP1 to SP3 may be at least partially separated due to the trench TRCH.

In some embodiments, the light emitting structure EMS may be formed through various suitable processes, such as vacuum deposition, inkjet printing, and/or the like. In this case, the same materials as those of the light emitting structure EMS may be disposed on bottom surfaces adjacent to the via layer VIAL of the trench TRCH.

The separator SPR may be provided in various suitable forms so that the light emitting structure EMS may have discontinuous portions at the boundary area BDA. In some embodiments, inorganic insulating patterns additionally stacked on the pixel definition layer PDL may be provided at the boundary area BDA without the trench TRCH. In this case, the width of the uppermost inorganic insulating pattern among the additionally stacked inorganic insulating patterns, may be greater than the width of the inorganic insulating pattern disposed directly thereunder. For example, at the boundary area BDA, first to third inorganic insulating patterns may be sequentially stacked from the pixel defining layer PDL, and the uppermost third inorganic insulating pattern may have a greater width than the second inorganic insulating pattern. For example, the pixel defining layer PDL may have a “T”-shaped or “I”-shaped cross section at the boundary area BDA. Depending on the shape of the pixel definition layer PDL, the plurality of layers included in the light emitting structure EMS may be at least partially broken or bent at the boundary area (BDA).

The light emitting structure EMS may be disposed on the anode electrodes AE exposed by the opening OP of the pixel definition layer PDL. The light emitting structure EMS may fill the opening OP of the pixel defining layer PDL, and may be disposed entirely over the first to third sub-pixels SP1 to SP3. As described above, the light emitting structure EMS may be at least partially broken or bent at the boundary area BDA due to the separator SPR. Accordingly, when the display panel DP is operated, a current flowing out from each of the first to third sub-pixels SP1 to SP3 to the neighboring sub-pixel through the layers included in the light emitting structure EMS may decrease. Accordingly, the first to third light emitting elements LD1 to LD3 may operate with a relatively high reliability.

The cathode electrode CE (e.g., a second electrode) may be disposed on the light emitting structure EMS. The cathode electrode CE may be commonly provided to the first to third sub-pixels SP1 to SP3. The cathode electrode CE may function as a half mirror that partially transmits and partially reflects light emitted from the light emitting structure EMS. For example, the thickness of the cathode electrode CE in the third direction DR3 may be 3 nm or more and 14 nm or less.

The first anode electrode AE1, the portion of the light emitting structure EMS overlapping with the first anode electrode AE1, and the portion of the cathode electrode CE overlapping with the first anode electrode AE1 may constitute the first light emitting element LD1. The second anode electrode AE2, the portion of the light emitting structure EMS overlapping with the second anode electrode AE2, and the portion of the cathode electrode CE overlapping with the second anode electrode AE2 may constitute the second light emitting element LD2. The third anode electrode AE3, the portion of the light emitting structure EMS overlapping with the third anode electrode AE3, and the portion of the cathode electrode CE overlapping with the third anode electrode AE3 may constitute the third light emitting element LD3.

The cathode electrode CE may be partially disconnected between the first to third sub-pixels SP1 to SP3 (e.g., at the boundary area BDA). For example, the cathode electrode CE may include a disconnection portion TC disposed between the first to third sub-pixels SP1 to SP3 (e.g., at the boundary area BDA).

A width WT of the disconnection portion TC of the cathode electrode CE in the first direction DR1 may be smaller than a width WO of the opening OP of the pixel definition layer PDL in the first direction DR1. For example, the width WT of the disconnection portion TC of the cathode electrode CE in the first direction DR1 may be less than 2.7% of the width WO of the opening OP of the pixel definition layer PDL in the first direction DR1. When the width WT of the disconnection portion TC of the cathode electrode CE in the first direction DR1 exceeds 2.7% of the width WO of the opening OP of the pixel definition layer PDL in the first direction DR1, the electrical characteristics of the display device may deteriorate.

The connection electrode TEL (e.g., a third electrode or a transparent electrode) may be disposed on the cathode electrode CE. The connection electrode TEL may serve to electrically connect the disconnected cathode electrode CE. Accordingly, even if the cathode electrode CE is partially disconnected, it may be possible to prevent or substantially prevent a decrease in a reliability of the display device 100. As such, the thickness of the connection electrode TEL in the third direction DR3 may be 5 nm or more and 200 nm or less.

The connection electrode TEL may be disposed on the disconnection portion TC of the cathode electrode CE. The connection electrode TEL may overlap with the disconnection portion TC of the cathode electrode CE in the third direction DR3. The connection electrode TEL may be disposed within the disconnection portion TC of the cathode electrode CE.

The connection electrode TEL may be disposed over the first to third sub-pixels SP1 to SP3. For example, the connection electrode TEL may overlap with the first to third sub-pixels SP1 to SP3 in the third direction DR3. The connection electrode TEL may overlap with the opening OP of the pixel definition layer PDL in the third direction DR3. In this case, the connection electrode TEL may include a transparent conductive material. For example, the connection electrode TEL may include at least one of various suitable transparent conductive materials, such as indium tin oxide (ITO), indium zinc oxide (IZO), zinc oxide (ZnOx), indium gallium zinc oxide (IGZO), or indium tin zinc oxide (ITZO).

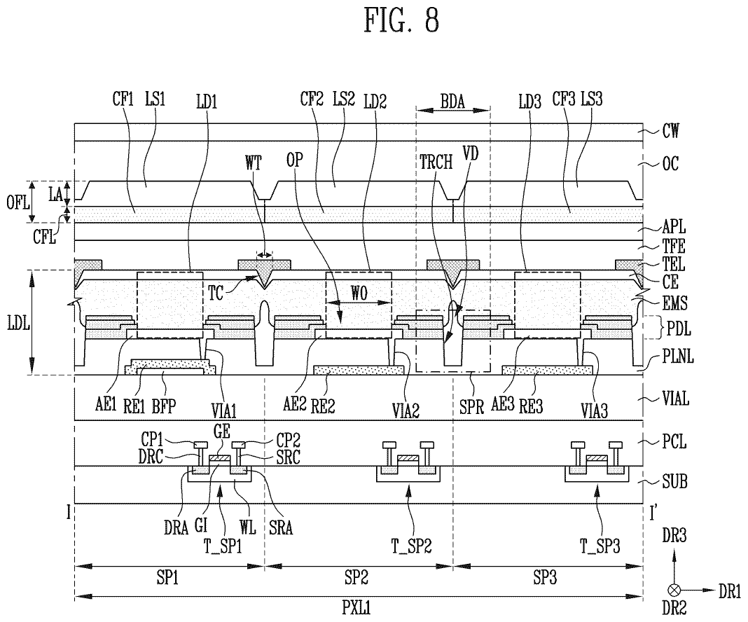

According to an embodiment, as shown in FIG. 8, the connection electrode TEL may be disposed between the first to third sub-pixels SP1 to SP3 (e.g., at the boundary area BDA). For example, the connection electrode TEL may overlap with the pixel definition layer PDL in the third direction DR3. The connection electrode TEL may not overlap with the opening OP of the pixel definition layer PDL in the third direction DR3. In this case, the connection electrode TEL may include a transparent, translucent, and/or opaque conductive material. For example, the connection electrode TEL may include at least one of indium tin oxide (ITO), indium zinc oxide (IZO), zinc oxide (ZnOx), indium gallium zinc oxide (IGZO), or indium tin zinc oxide (ITZO). As another example, the connection electrode TEL may include at least one of silver (Ag), magnesium (Mg), and/or suitable mixtures thereof.

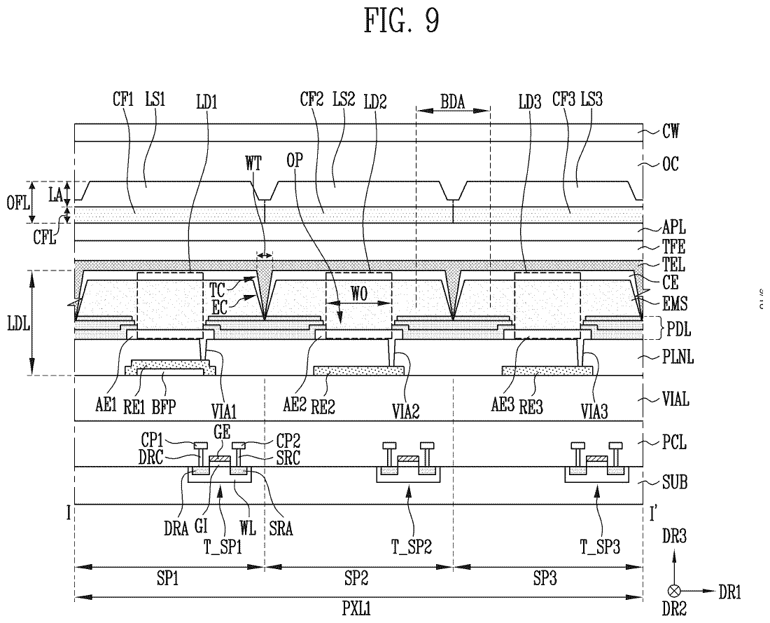

According to an embodiment, as shown in FIG. 9, the light emitting structure EMS and the cathode electrode CE may include disconnection portions EC and TC. The light emitting structure EMS may be partially disconnected between the first to third sub-pixels SP1 to SP3 (e.g., at the boundary area BDA). The light emitting structure EMS may include the disconnection portion EC disposed between the first to third sub-pixels SP1 to SP3 (e.g., at the boundary area BDA).

The cathode electrode CE may be partially disconnected between the first to third sub-pixels SP1 to SP3 (e.g., at the boundary area BDA). For example, the cathode electrode CE may include the disconnection portion TC disposed between the first to third sub-pixels SP1 to SP3 (e.g., at the boundary area BDA).

A width WT of the disconnection portion TC of the cathode electrode CE in the first direction DR1 may be smaller than a width WO of the opening OP of the pixel definition layer PDL in the first direction DR1. For example, the width WT of the disconnection portion TC of the cathode electrode CE in the first direction DR1 may be less than 2.7% of the width WO of the opening OP of the pixel definition layer PDL in the first direction DR1.

The disconnection portion TC of the cathode electrode CE may overlap with the disconnection portion EC of the light emitting structure EMS in the third direction DR3. The cathode electrode CE may be disposed within the disconnection portion EC of the light emitting structure EMS. The disconnection portion EC of the light emitting structure EMS and the disconnection portion TC of the cathode electrode CE may be formed sequentially. For example, the disconnection portion EC may be formed by drilling the light emitting structure EMS using a laser, and then the cathode electrode CE may be formed on the light emitting structure EMS. Subsequently, the disconnection portion TC may be formed by drilling the cathode electrode CE using a laser, and then the connection electrode TEL may be formed on the cathode electrode CE. However, the present disclosure is not necessarily limited thereto.

The connection electrode TEL may be disposed on the cathode electrode CE. The connection electrode TEL may serve to electrically connect the disconnected cathode electrode CE. Accordingly, as described above, a decrease in the reliability of the display device 100 may be prevented or substantially prevent, even if the cathode electrode CE is partially disconnected. As such, the thickness of the connection electrode TEL in the third direction DR3 may be 5 nm or more and 200 nm or less.

The connection electrode TEL may be disposed on the disconnection portion TC of the cathode electrode CE. The connection electrode TEL may be provided within the disconnection portion TC of the cathode electrode CE. The connection electrode TEL may overlap with the disconnection portion TC of the cathode electrode CE in the third direction DR3. The connection electrode TEL may be disposed within the disconnection portion TC of the cathode electrode CE.

The connection electrode TEL may be disposed over the first to third sub-pixels SP1 to SP3. For example, the connection electrode TEL may overlap with the first to third sub-pixels SP1 to SP3 in the third direction DR3. The connection electrode TEL may overlap with the opening OP of the pixel definition layer PDL in the third direction DR3. In this case, the connection electrode TEL may include a transparent conductive material. For example, the connection electrode TEL may include at least one of various suitable transparent conductive materials, such as indium tin oxide (ITO), indium zinc oxide (IZO), zinc oxide (ZnOx), indium gallium zinc oxide (IGZO), or indium tin zinc oxide (ITZO).

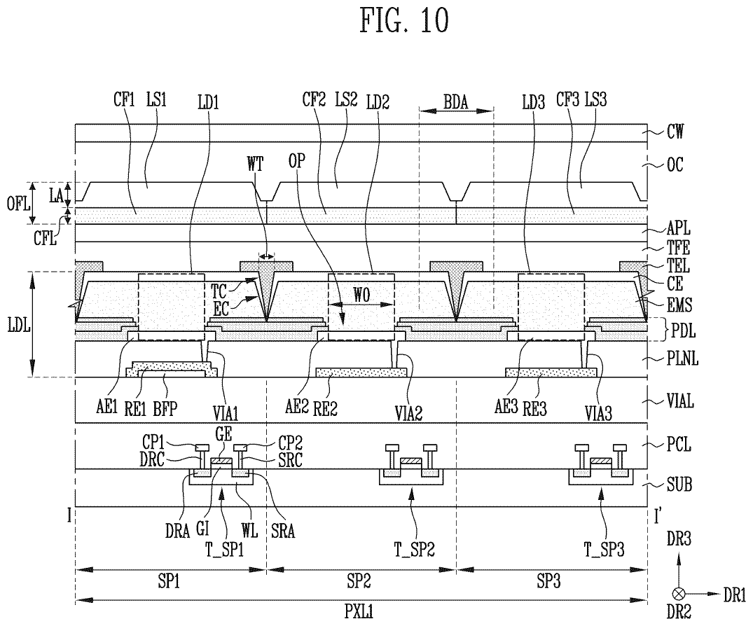

According to an embodiment, as shown in FIG. 10, the connection electrode TEL may be disposed between the first to third sub-pixels SP1 to SP3 (e.g., at the boundary area BDA). For example, the connection electrode TEL may overlap with the pixel definition layer PDL in the third direction DR3. The connection electrode TEL may not overlap with the opening OP of the pixel definition layer PDL in the third direction DR3. In this case, the connection electrode TEL may include a transparent, translucent, and/or opaque conductive material. For example, the connection electrode TEL may include at least one of indium tin oxide (ITO), indium zinc oxide (IZO), zinc oxide (ZnOx), indium gallium zinc oxide (IGZO), or indium tin zinc oxide (ITZO). As another example, the connection electrode TEL may include at least one of silver (Ag), magnesium (Mg), and/or suitable mixtures thereof.

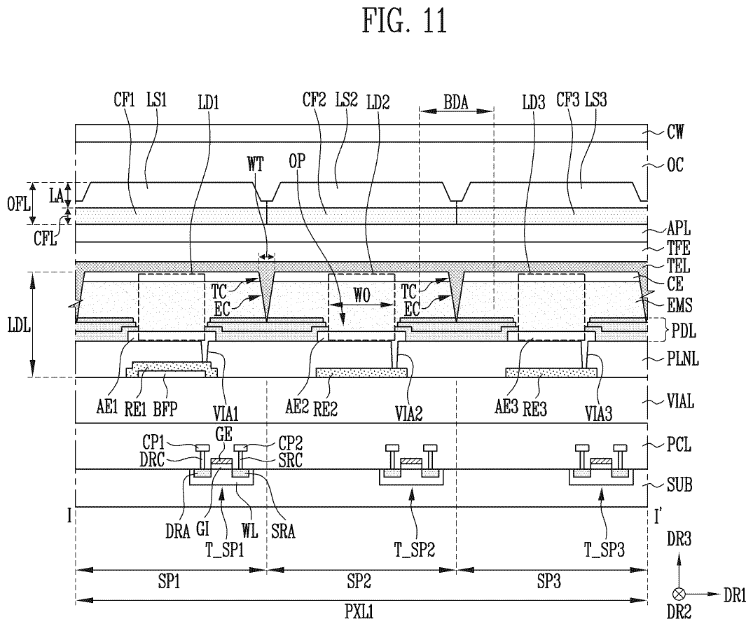

According to an embodiment, as shown in FIG. 11, the disconnection portion TC of the cathode electrode CE may overlap with the disconnection portion EC of the light emitting structure EMS in the third direction DR3. The disconnection portion TC of the cathode electrode CE may be formed concurrently with (e.g., simultaneously or substantially simultaneously with) the disconnection portion EC of the light emitting structure EMS in the same process as each other, but the present disclosure is not necessarily limited thereto. For example, the disconnection portion TC of the cathode electrode CE and the disconnection portion EC of the light emitting structure EMS may be formed concurrently (e.g., simultaneously or substantially simultaneously) with each other by laser drilling, but the present disclosure is not limited thereto.

The connection electrode TEL may be disposed on the disconnection portion EC of the light emitting structure EMS and the disconnection portion TC of the cathode electrode CE. The connection electrode TEL may overlap with the disconnection portion EC of the light emitting structure EMS and the disconnection portion TC of the cathode electrode CE in the third direction DR3. The connection electrode TEL may be disposed within the disconnection portion EC of the light emitting structure EMS and the disconnection portion TC of the cathode electrode CE.

The connection electrode TEL may be disposed over the first to third sub-pixels SP1 to SP3. For example, the connection electrode TEL may overlap with the first to third sub-pixels SP1 to SP3 in the third direction DR3. The connection electrode TEL may overlap with the opening OP of the pixel definition layer PDL in the third direction DR3. In this case, the connection electrode TEL may include a transparent conductive material. For example, the connection electrode TEL may include at least one of various suitable transparent conductive materials, such as indium tin oxide (ITO), indium zinc oxide (IZO), zinc oxide (ZnOx), indium gallium zinc oxide (IGZO), or indium tin zinc oxide (ITZO).

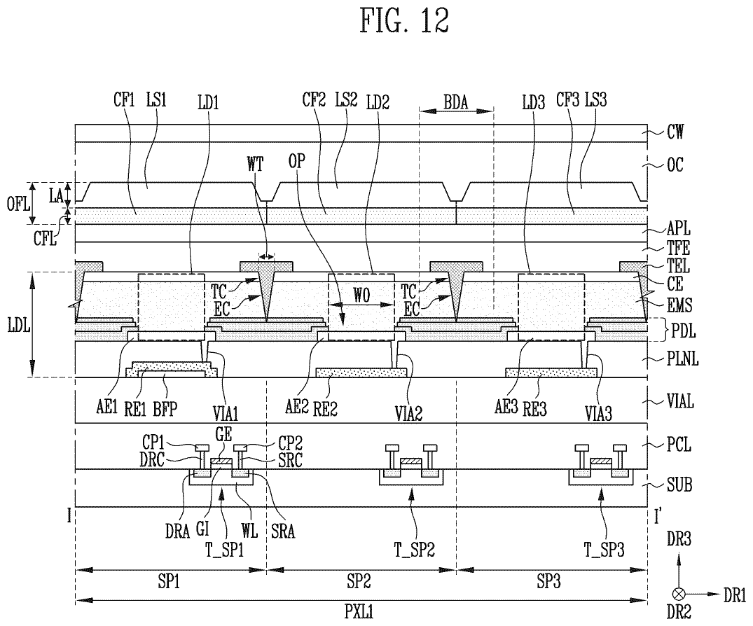

According to an embodiment, as shown in FIG. 12, the connection electrode TEL may be disposed between the first to third sub-pixels SP1 to SP3 (e.g., at the boundary area BDA). For example, the connection electrode TEL may overlap with the pixel definition layer PDL in the third direction DR3. The connection electrode TEL may not overlap with the opening OP of the pixel definition layer PDL in the third direction DR3. In this case, the connection electrode TEL may include a transparent, translucent, and/or opaque conductive material. For example, the connection electrode TEL may include at least one of indium tin oxide (ITO), indium zinc oxide (IZO), zinc oxide (ZnOx), indium gallium zinc oxide (IGZO), or indium tin zinc oxide (ITZO). As another example, the connection electrode TEL may include at least one of silver (Ag), magnesium (Mg), and/or suitable mixtures thereof.

The encapsulation layer TFE may be disposed on the connection electrode TEL. The encapsulation layer TFE may prevent or substantially prevent oxygen and/or moisture from penetrating into the light emitting element layer LDL.

An optical functional layer OFL may be disposed on the encapsulation layer TFE. In some embodiments, the optical functional layer OFL may be attached to the encapsulation layer TFE by using an adhesive layer APL. For example, the optical functional layer OFL may be manufactured separately, and then attached to the encapsulation layer TFE through the adhesive layer APL. The adhesive layer APL may further perform a function of protecting the lower layers including the encapsulation layer TFE.

The optical functional layer OFL may include a color filter layer CFL and a lens array LA. The color filter layer CFL may include first to third color filters CF1 to CF3 corresponding to the first to third sub-pixels SP1 to SP3, respectively. The first to third color filters CF1 to CF3 may pass light of different wavelength ranges from each other. For example, the first to third color filters CF1 to CF3 may pass light of red, green, and blue colors, respectively.

In some embodiments, the first to third color filters CF1 to CF3 may partially overlap with each other at the boundary area BDA. In other embodiments, the first to third color filters CF1 to CF3 may be spaced apart from each other, and a black matrix may be provided between the first to third color filters CF1 to CF3.

The lens array LA may be disposed on the color filter layer CFL. The lens array LA may include first to third lenses LS1 to LS3 corresponding to the first to third sub-pixels SP1 to SP3, respectively. The first to third lenses LS1 to LS3 may improve light output efficiency by outputting the light emitted from the first to third light emitting elements LD1 to LD3, respectively, along an intended path.

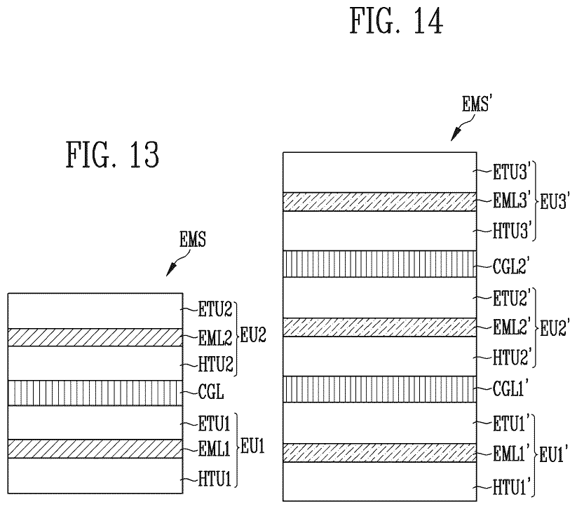

FIG. 13 is a cross-sectional view showing a light emitting structure included in any one of the first to third light emitting elements of FIGS. 7 to 12 according to an embodiment.

Referring to FIG. 13, the light emitting structure EMS may have a tandem structure including first and second light emitting units (e.g., first and second light emitting layers) EU1 and EU2 that are stacked. The light emitting structure EMS in each of the first to third light emitting elements LD1 to LD3 of FIGS. 7 to 12 may be configured the same or substantially the same as each other.

Each of the first and second light emitting units EU1 and EU2 may include at least one emission layer that generates light depending on an applied current. The first light emitting unit EU1 may include a first light emission layer EML1, a first electron transport unit (e.g., a first electron transport layer) ETU1, and a first hole transport unit (e.g., a first hole transport layer) HTU1. The first emission layer EML1 may be disposed between the first electron transport unit ETU1 and the first hole transport unit HTU1. The second light emitting unit EU2 may include a second light emission layer EML2, a second electron transport unit (e.g., a second electron transport layer) ETU2, and a second hole transport unit (e.g., a second hole transport layer) HTU2. The second emission layer EML2 may be disposed between the second electron transport unit ETU2 and the second hole transport unit HTU2.

Each of the first and second hole transport units HTU1 and HTU2 may include at least one of a hole injection layer and/or a hole transport layer, and may further include a hole buffer layer and/or an electron blocking layer, if necessary or desired. The first and second hole transport units HTU1 and HTU2 may have the same or substantially the same configuration as each other, or may have different configurations from each other.

Each of the first and second electron transport units ETU1 and ETU2 may include at least one of an electron injection layer and/or an electron transport layer, and may further include an electron buffer layer and/or a hole blocking layer, if necessary or desired. The first and second electron transport units ETU1 and ETU2 may have the same or substantially the same configuration as each other, or may have different configurations from each other.

A connection layer, which may be provided in the form of a charge generation layer CGL, may be disposed between the first light emitting unit EU1 and the second light emitting unit EU2 to connect them to each other. In some embodiments, the charge generation layer CGL may have a stacked structure of a p dopant layer and an n dopant layer. For example, the p dopant layer may include a p-type dopant, such as HAT-CN, TCNQ, NDP-9, and/or the like. The n dopant layer may include an alkali metal, an alkaline earth metal, a lanthanide metal, or a suitable combination thereof. However, the present disclosure is not limited thereto.

In some embodiments, the first emission layer EML1 and the second emission layer EML2 may generate light of different colors from each other. The light emitted from each of the first and second light emission layers EML1 and EML2 may be mixed with each other and viewed as white light. For example, the first emission layer EML1 may generate blue-colored light, and the second emission layer EML2 may generate yellow-colored light. In some embodiments, the second emission layer EML2 may include a structure in which a first sub-emission layer configured to generate red-colored light and a second sub-emission layer configured to generate green-colored light are stacked. The red-colored light and green-colored light may be mixed with each other to provide yellow-colored light. In this case, an intermediate layer to perform a function of transporting holes and/or preventing or substantially prevent transport of electrons may be further disposed between the first and second sub-emission layers.

In other embodiments, the first emission layer EML1 and the second emission layer EML2 may generate light of the same color as each other.

The light emitting structure EMS may be formed through various suitable methods, such as vacuum deposition and inkjet printing, but the present disclosure is not limited thereto.

FIG. 14 is a cross-sectional view showing a light emitting structure included in any one of the first to third light emitting elements of FIGS. 7 to 12 according to an embodiment.

Referring to FIG. 14, the light emitting structure EMS′ may have a tandem structure including first to third light emitting units (e.g., first to third light emitting layers) EU1′ to EU3′ that are stacked. The light emitting structure EMS′ in each of the first to third light emitting elements LD1 to LD3 of FIGS. 7 to 12 may be configured the same or substantially the same as each other.

Each of the first to third light emitting units EU1′ to EU3′ may include a light emission layer that generates light depending on an applied current. The first light emitting unit EU1′ may include a first light emission layer EML1′, a first electron transport unit (e.g., a first electron transport layer) ETU1′, and a first hole transport unit (e.g., a first hole transport layer) HTU1′. The first emission layer EML1′ may be disposed between the first electron transport unit ETU1′ and the first hole transport unit HTU1′. The second light emitting unit EU2′ may include a second light emission layer EML2′, a second electron transport unit (e.g., a second electron transport layer) ETU2′, and a second hole transport unit (e.g., a second hole transport layer) HTU2′. The second emission layer EML2′ may be disposed between the second electron transport unit ETU2′ and the second hole transport unit HTU2′. The third light emitting part EU3′ may include a third emission layer EML3′, a third electron transport unit (e.g., a third electron transport layer) ETU3′, and a third hole transport unit (e.g., a third hole transport layer) HTU3′. The third emission layer EML3′ may be disposed between the third electron transport unit ETU3′ and the third hole transport unit HTU3′.

Each of the first to third hole transport units HTU1′ to HTU3′ may include at least one of a hole injection layer or a hole transport layer, and may further include a hole buffer layer, an electron blocking layer, and/or the like, if necessary or desired. The first to third hole transport units HTU1′ to HTU3′ may have the same or substantially the same configuration as each other, or may have different configurations from each other.

Each of the first to third electron transport units ETU1′ to ETU3′ may include at least one of an electron injection layer or an electron transport layer, and may further include an electron buffer layer, a hole blocking layer, and/or the like, if necessary or desired. The first to third electron transport units ETU1′ to ETU3′ may have the same or substantially the same configuration as each other, or may have different configurations from each other.

The first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

In some embodiments, the first to third emission layers EML1′ to EML3′ may generate light of different colors from each other. The light emitted from each of the first to third emission layers EML1′ to EML3′ may be mixed with each other, and viewed as white light. For example, the first emission layer EML1′ may generate blue-colored light, the second emission layer EML2′ may generate green-colored light, and the third emission layer EML3′ may generate red-colored light.

In other embodiments, two or more of the first to third emission layers EML1′ to EML3′ may generate light of the same color as each other.

Unlike those shown in FIGS. 13 and 14, the light emitting structures EMS of FIGS. 7 to 12 may include one light emitting unit (e.g., one light emitting layer) in each of the first to third light emitting elements LD1 to LD3. In this case, the light emitting unit included in each of the first to third light emitting elements LD1 to LD3 may emit light of different colors from each other. For example, the light emitting unit of the first light emitting element LD1 may emit red-colored light, the light emitting unit of the second light emitting element LD2 may emit green-colored light, and the light emitting unit of the third light emitting element LD3 may emit blue-colored light. In this case, unlike those shown in FIGS. 7 to 12, the light emitting units of the first to third sub-pixels SP1 to SP3 may be spaced apart (e.g., may be separated) from each other, and each thereof may be disposed within a corresponding opening OP of the pixel definition layer PDL. In this case, at least some of the color filters CF1 to CF3 may be omitted as needed or desired.

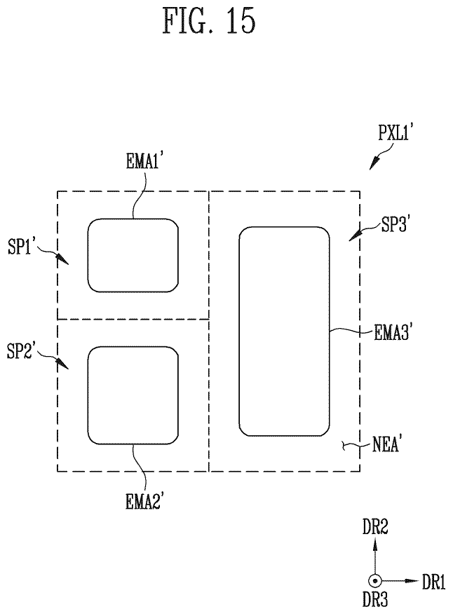

FIG. 15 is a plan view showing a pixel of FIG. 5 according to an embodiment. Referring to FIG. 15, the first pixel PXL1′ may include first to third sub-pixels SP1′ to SP3′.

The first sub-pixel SP1′ may include a first emission area EMA1′, and a non-emission area NEA′ around (e.g., surrounding around a periphery of) the first emission area EMA1′. The second sub-pixel SP2′ may include a second emission area EMA2′, and a non-emission area NEA′ around (e.g., surrounding around a periphery of) the second emission area EMA2′. The third sub-pixel SP3′ may include a third emission area EMA3′, and a non-emission area NEA′ around (e.g., surrounding around a periphery of) the third emission area EMA3′.

The first sub-pixel SP1′ and the second sub-pixel SP2′ may be arranged along the second direction DR2. The third sub-pixel SP3′ may be arranged along the first direction DR1 with respect to each of the first and second sub-pixels SP1′ and SP2′.

The second sub-pixel SP2′ may have a larger area than that of the first sub-pixel SP1′, and the third sub-pixel SP3′ may have a larger area than that of the second sub-pixel SP2′. Accordingly, the second emission area EMA2′ may have a larger area than that of the first emission area EMA1′, and the third emission area EMA3′ may have a larger area than that of the second emission area EMA2′. However, the present disclosure is not limited thereto. For example, the first and second sub-pixels SP1′ and SP2′ may have the same or substantially the same area as each other, and the third sub-pixel SP3′ may have a greater area than those of each of the first and second sub-pixels SP1′ and SP2′. As such, the areas of the first to third sub-pixels SP1′ to SP3′ may be variously modified as needed or desired.

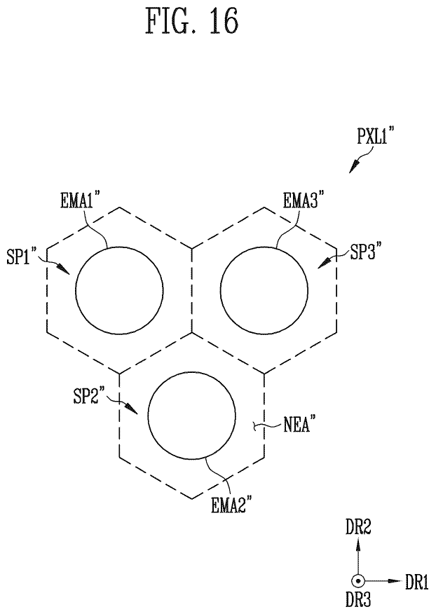

FIG. 16 is a plan view showing a pixel of FIG. 5 according to an embodiment.

Referring to FIG. 16, the first sub-pixel SP1″ may include a first emission area EMA1″, and a non-emission area NEA″ around (e.g., surrounding around a periphery of) the first emission area EMA1″. The second sub-pixel SP2″ may include a second emission area EMA2″, and a non-emission area NEA″ around (e.g., surrounding around a periphery of) the second emission area EMA2″. The third sub-pixel SP3″ may include a third emission area EMA3″, and a non-emission area NEA″ around (e.g., surrounding around a periphery of) the third emission area EMA3″.

The first to third sub-pixels SP1″ to SP3″ may have polygonal shapes when viewed in the third direction DR3 (e.g., in a plan view). For example, the first to third sub-pixels SP1″ to SP3″ may have hexagonal shapes as shown in FIG. 16.

The first to third emission areas EMA1″ to EMA3″ may have circular shapes when viewed in the third direction DR3 (e.g., in a plan view). However, the present disclosure is not limited thereto. For example, each of the first to third emission areas EMA1″ to EMA3″ may have a polygonal shape.

The first and third sub-pixels SP1″ and SP3″ may be arranged along the first direction DR1. The second sub-pixel SP2″ may be arranged along a direction inclined at an acute angle (e.g., diagonally) with respect to the second direction DR2 and with respect to the first sub-pixel SP1″.

However, the present disclosure is not limited to the arrangements of the sub-pixels shown in FIGS. 6, 15, and 16. Each pixel may include two or more sub-pixels, the sub-pixels may be arranged in various suitable ways, each of the sub-pixels may have various suitable shapes, and each of emission areas thereof may have various suitable shapes.

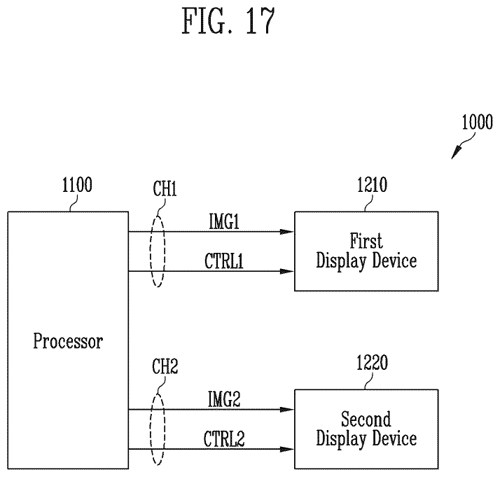

FIG. 17 is a block diagram showing a display system according to an embodiment.

Referring to FIG. 17, the display system 1000 may include a processor 1100, and one or more display devices 1210 and 1220.

The processor 1100 may perform various suitable tasks and calculations. In some embodiments, the processor 1100 may include an application processor, a graphics processor, a microprocessor, a central processing unit (CPU), and/or the like. The processor 1100 may be connected to and control other components of the display system 1000 through a bus system.

In FIG. 17, the display system 1000 is shown as including first and second display devices 1210 and 1220. The processor 1100 may be connected to the first display device 1210 through a first channel CH1, and may be connected to the second display device 1220 through a second channel CH2.

Through the first channel CH1, the processor 1100 may transmit the first image data IMG1 and the first control signal CTRL1 to the first display device 1210. The first display device 1210 may display an image based on the first image data IMG1 and the first control signal CTRL1. The first display device 1210 may be configured similarly to the display device 100 described above with reference to FIG. 1. In this case, the first image data IMG1 and the first control signal CTRL1 may be provided as the input image data IMG and control signal CTRL described above with reference to FIG. 1, respectively.

Through the second channel CH2, the processor 1100 may transmit the second image data IMG2 and the second control signal CTRL2 to the second display device 1220. The second display device 1220 may display an image based on the second image data IMG2 and the second control signal CTRL2. The second display device 1220 may be configured similarly to the display device 100 described above with reference to FIG. 1. In this case, the second image data IMG2 and the second control signal CTRL2 may be provided as the input image data IMG and control signal CTRL described above with reference to FIG. 1, respectively.

The display system 1000 may include a computing system that provides image display functions, such as a portable computer, a mobile phone, a smart phone, a tablet personal computer, a smart watch, a watch phone, a portable multimedia player (PMP), a navigation, an ultra mobile personal computer (UMPC), and/or the like. The display system 1000 may include at least one of a head mounted display (HMD) device, a virtual reality (VR) device, a mixed reality (MR) device, an augmented reality (AR) device, or the like.

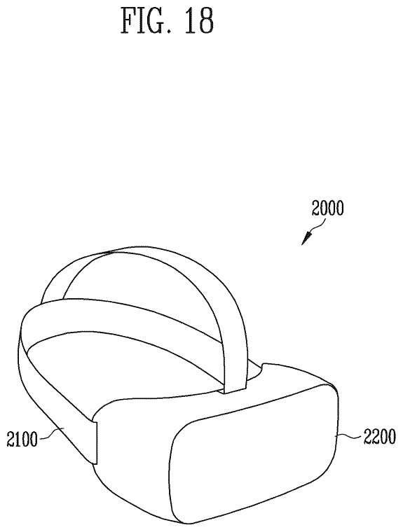

FIG. 18 is a perspective view showing an application of the display system of FIG. 17 according to an embodiment.

Referring to FIG. 18, the display system 1000 described above with reference to FIG. 17 may be applied to a head mounted display device 2000. The head mounted display device 2000 may be a wearable electronic device that may be worn on the user's head.

The head mounted display device 2000 may include a head mounted band 2100 and a display device storage case 2200. The head mounted band 2100 may be connected to the display device storage case 2200. The head mounted band 2100 may include a horizontal band and/or a vertical band for fixing the head mounted display device 2000 to the user's head. The horizontal band may surround the sides of the user's head, and the vertical band may surround the top of the user's head. However, the present disclosure is not limited thereto. For example, the head mounted band 2100 may be implemented in the form of glasses frames, helmets, and/or the like.

The display device storage case 2200 may accommodate the first and second display devices 1210 and 1220 described above with reference to FIG. 17. The display device storage case 2200 may further accommodate the processor 1100 described above with reference to FIG. 17.

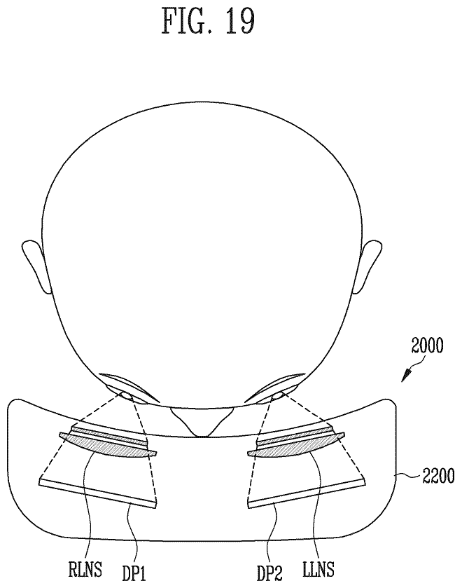

FIG. 19 is a drawing showing a head-mounted display device of FIG. 18 worn by a user.

Referring to FIG. 19, a first display panel DP1 of the first display device 1210 and a second display panel DP2 of the second display device 1220 may be disposed in the head mounted display device 2000. The head mounted display device 2000 may further include one or more lenses LLNS and RLNS.

In the display device storage case 2200, a right eye lens RLNS may be disposed between the first display panel DP1 and the user's right eye. In the display device storage case 2200, a left eye lens LLNS may be disposed between the second display panel DP2 and the user's left eye.

The image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function to adjust a viewing distance between the first display panel DP1 and the user's right eye.

The image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function to adjust a viewing distance between the second display panel DP2 and the user's left eye.

In some embodiments, each of the right eye lens RLNS and the left eye lens LLNS may include an optical lens having a pancake-shaped cross section. In some embodiments, each of the right eye lens RLNS and the left eye lens LLNS may include a multi-channel lens including sub-areas with different optical properties. In this case, each display panel may output images corresponding to the sub-areas of the multi-channel lens, and the output images may pass through the corresponding sub-areas to be viewed by the user.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

1 what is claimed is:

1. A display device comprising:
a first sub-pixel; and
a second sub-pixel,
wherein each of the first sub-pixel and the second sub-pixel comprises:
a first electrode;
a pixel definition layer on the first electrode, and having an opening;
a light emitting structure on the first electrode and the pixel definition layer;
a second electrode on the light emitting structure, and having a disconnection portion; and
a third electrode on the second electrode, and overlapping with the disconnection portion, and
wherein a width of the disconnection portion in a first direction is 2.7% or less of a width of the opening in the first direction.

2. The display device of claim 1, wherein the disconnection portion is located between the first sub-pixel and the second sub-pixel.

3. The display device of claim 1, wherein the light emitting structure is at least partially separated between the first sub-pixel and the second sub-pixel.

4. The display device of claim 1, wherein the third electrode is located within the disconnection portion.

5. The display device of claim 1, wherein the third electrode overlaps with the opening.

6. The display device of claim 5, wherein the third electrode comprises a transparent conductive material.

7. The display device of claim 1, wherein the third electrode does not overlap with the opening.

8. The display device of claim 7, wherein the third electrode comprises at least one of a transparent conductive material, a translucent conductive material, or an opaque conductive material.

9. The display device of claim 1, wherein the third electrode is located between the first sub-pixel and the second sub-pixel.

10. The display device of claim 1, wherein a thickness of the second electrode is 3 nm or more and 14 nm or less.

11. The display device of claim 1, wherein a thickness of the third electrode is 5 nm or more and 200 nm or less.

12. A display device comprising:
a first sub-pixel; and
a second sub-pixel,
wherein each of the first sub-pixel and the second sub-pixel comprises:
a first electrode;
a pixel definition layer on the first electrode, and having an opening;
a light emitting structure on the first electrode and the pixel definition layer, and having a first disconnection portion;
a second electrode on the light emitting structure, and having at least one second disconnection portion; and
a third electrode on the second electrode, and overlapping with the second disconnection portion, and
wherein a width of the second disconnection portion in a first direction is 2.7% or less of a width of the opening in the first direction.

13. The display device of claim 12, wherein the second disconnection portion overlaps with the first disconnection portion.

14. The display device of claim 12, wherein the second electrode is located within the first disconnection portion.

15. The display device of claim 14, wherein the third electrode is located within the second disconnection portion.

16. The display device of claim 12, wherein the third electrode is located within the first disconnection portion and the second disconnection portion.

17. The display device of claim 12, wherein the first disconnection portion and the second disconnection portion are located between the first sub-pixel and the second sub-pixel.

18. The display device of claim 12, wherein the third electrode comprises a transparent conductive material.

19. The display device of claim 12, wherein a thickness of the second electrode is 3 nm or more and 14 nm or less.

20. The display device of claim 12, wherein a thickness of the third electrode is 5 nm or more and 200 nm or less.
